(19) United States
(12) Patent Application Publication
(10) Pub. No.: US 2022/0101782 A1
(43) Pub. Date: Mar. 31, 2022

(54) SHIFT REGISTER AND DRIVING METHOD THEREOF, GATE DRIVING CIRCUIT AND DISPLAY APPARATUS

(71) Applicants: CHENGDU BOE OPTOELECTRONICS TECHNOLOGY CO., LTD., Chengdu (CN); BOE TECHNOLOGY GROUP CO., LTD., Beijing (CN)

(72) Inventors: Chengchung YANG, Beijing (CN); Yucheng CHAN, Beijing (CN); Wei LIU, Beijing (CN); Weitao MA, Beijing (CN); Bo YANG, Beijing (CN)

(21) Appl. No.: 17/474,294

(22) Filed: Sep. 14, 2021

(30) Foreign Application Priority Data
Sep. 28, 2020 (CN) 202011043536.3

(51) Int. Cl. G09G 3/32; G11C 19/28

(52) U.S. Cl. CPC G09G 3/32; G11C 19/28; G09G 2310/0286; G09G 2300/0408; G09G 2310/0267; G09G 2300/0426; G09G 2300/08; G09G 2310/08

(57) ABSTRACT

A shift register includes an input circuit, a first control circuit, a first output circuit, and a second output circuit. The input circuit is configured to transmit an input signal received at an input terminal to a first node in response to a first clock signal received at a first clock signal terminal. The first control circuit is configured to transmit a first voltage of a first voltage terminal to a second node in response to the first clock signal received at the first clock signal terminal. The first output circuit is configured to transmit a second clock signal received at a second clock signal terminal to an output terminal in response to a voltage of the first node. The second output circuit is configured to transmit a second voltage of a second voltage terminal to the output terminal in response to a voltage of the second node.

### CROSS-REFERENCE TO RELATED APPLICATION

This application claims priority to Chinese Patent Application No. 202011043536.3, filed on Sep. 28, 2020, which is incorporated herein by reference in its entirety.

### TECHNICAL FIELD

The present disclosure relates to the field of display technologies, and in particular, to a shift register and a driving method thereof, a gate driving circuit, and a display apparatus.

### BACKGROUND

A gate driver on array (GOA) is a technique used to sequentially drive and scan gate lines row by row. By using the GOA technique, a gate driving circuit can be integrated in an array substrate of a display panel, so as to reduce the cost and difficulty of manufacturing the display panel.

### SUMMARY

In an aspect, a shift register is provided. The shift register includes: an input circuit, a first control circuit, a first output circuit, and a second output circuit. The input circuit is coupled to at least a first clock signal terminal, an input terminal, and a first node. The first control circuit is coupled to the first clock signal terminal, a first voltage terminal, and a second node. The first output circuit is coupled to the first node, a second clock signal terminal, and an output terminal. The second output circuit is coupled to the second node, a second voltage terminal, and the output terminal. The input circuit is configured to transmit an input signal received at the input terminal to the first node in response to a first clock signal received at the first clock signal terminal. The first control circuit is configured to transmit a first voltage of the first voltage terminal to the second node in response to the first clock signal received at the first clock signal terminal. The first output circuit is configured to transmit a second clock signal received at the second clock signal terminal to the output terminal in response to a voltage of the first node. The second output circuit is configured to transmit a second voltage of the second voltage terminal to the output terminal in response to a voltage of the second node.

In some embodiments, the input circuit includes a first transistor. A control electrode of the first transistor is coupled to the first clock signal terminal, a first electrode of the first transistor is coupled to the input terminal, and a second electrode of the first transistor is coupled to the first node.

In some embodiments, the input circuit is further coupled to the first voltage terminal. The input circuit is configured to transmit the input signal to the first node in response to the first clock signal and the first voltage of the first voltage terminal.

In some embodiments, the input circuit includes a first input sub-circuit and a second input sub-circuit. The first input sub-circuit is coupled to the first clock signal terminal, the input terminal, and a third node. The second input sub-circuit is coupled to the third node, the first voltage terminal, and the first node. The first input sub-circuit is configured to transmit the input signal to the third node in response to the first clock signal. The second input sub-circuit is configured to connect the first input sub-circuit to the first node in response to the first voltage of the first voltage terminal.

In some embodiments, the first input sub-circuit includes a second transistor. A control electrode of the second transistor is coupled to the first clock signal terminal, a first electrode of the second transistor is coupled to the input terminal, and a second electrode of the second transistor is coupled to the third node. The second input sub-circuit includes a third transistor. A control electrode of the third transistor is coupled to the first voltage terminal, a first electrode of the third transistor is coupled to the third node, and a second electrode of the third transistor is coupled to the first node.

In some embodiments, the first control circuit includes a fourth transistor. A control electrode of the fourth transistor is coupled to the first clock signal terminal, a first electrode of the fourth transistor is coupled to the first voltage terminal, and a second electrode of the fourth transistor is coupled to the second node.

In some embodiments, the first output circuit includes a fifth transistor and a first capacitor. A control electrode of the fifth transistor is coupled to the first node, a first electrode of the fifth transistor is coupled to the second clock signal terminal, and a second electrode of the fifth transistor is coupled to the output terminal. A first terminal of the first capacitor is coupled to the first node, and a second terminal of the first capacitor is coupled to the output terminal.

In some embodiments, the second output circuit includes a sixth transistor and a second capacitor. A control electrode of the sixth transistor is coupled to the second node, a first electrode of the sixth transistor is coupled to the second voltage terminal, and a second electrode of the sixth transistor is coupled to the output terminal. A first terminal of the second capacitor is coupled to the second voltage terminal, and a second terminal of the second capacitor is coupled to the second node.

In some embodiments, the shift register further includes a second control circuit. The second control circuit is coupled to the second node, the second voltage terminal, and the output terminal. The second control circuit is configured to transmit the second voltage of the second voltage terminal to the second node in response to the output signal at the output terminal.

In some embodiments, the second control circuit includes a seventh transistor. A control electrode of the seventh transistor is coupled to the output terminal, a first electrode of the seventh transistor is coupled to the second voltage terminal, and a second electrode of the seventh transistor is coupled to the second node.

In some embodiments, the shift register further includes a third control circuit. The third control circuit is coupled to the second clock signal terminal, the second voltage terminal, the second node, and the third node. The third control circuit is configured to transmit the second voltage of the second voltage terminal to the third node in response to the voltage of the second node and the second clock signal received at the second clock signal terminal.

In some embodiments, the third control circuit includes an eighth transistor and a ninth transistor. A control electrode of the eighth transistor is coupled to the second node, and a first electrode of the eighth transistor is coupled to the second voltage terminal. A control electrode of the ninth transistor is coupled to the second clock signal terminal, a first electrode of the ninth transistor is coupled to a second electrode of the eighth transistor, and a second electrode of the ninth transistor is coupled to the third node.

In some embodiments, the shift register further includes a storage circuit. The storage circuit is coupled to the output terminal and a fixed voltage terminal. The storage circuit is configured to store the output signal at the output terminal.

In some embodiments, the storage circuit includes a third capacitor. A first terminal of the third capacitor is coupled to the output terminal, and a second terminal of the third capacitor is coupled to the fixed voltage terminal.

In some embodiments, the shift register further includes a second control circuit and a third control circuit. The input circuit includes a first transistor, a control electrode of the first transistor is coupled to the first clock signal terminal, a first electrode of the first transistor is coupled to the input terminal, and a second electrode of the first transistor is coupled to the first node. The first control circuit includes a fourth transistor, a control electrode of the fourth transistor is coupled to the first clock signal terminal, a first electrode of the fourth transistor is coupled to the first voltage terminal, and a second electrode of the fourth transistor is coupled to the second node. The first output circuit includes a fifth transistor and a first capacitor; a control electrode of the fifth transistor is coupled to the first node, a first electrode of the fifth transistor is coupled to the second clock signal terminal, and a second electrode of the fifth transistor is coupled to the output terminal; and a first terminal of the first capacitor is coupled to the first node, and a second terminal of the first capacitor is coupled to the output terminal. The second output circuit includes a sixth transistor and a second capacitor; a control electrode of the sixth transistor is coupled to the second node; a first electrode of the sixth transistor is coupled to the second voltage terminal, and a second electrode of the sixth transistor is coupled to the output terminal; and a first terminal of the second capacitor is coupled to the second voltage terminal, and a second terminal of the second capacitor is coupled to the second node. The second control circuit includes a seventh transistor, a control electrode of the seventh transistor is coupled to the output terminal, a first electrode of the seventh transistor is coupled to the second voltage terminal, and a second electrode of the seventh transistor is coupled to the second node. The third control circuit includes an eighth transistor and a ninth transistor; a control electrode of the eighth transistor is coupled to the second node, and a first electrode of the eighth transistor is coupled to the second voltage terminal; and a control electrode of the ninth transistor is coupled to the second clock signal terminal, a first electrode of the ninth transistor is coupled to a second electrode of the eighth transistor, and a second electrode of the ninth transistor is coupled to the first node.

In some embodiments, the shift register further includes a second control circuit and a third control circuit. The input circuit is further coupled to the first voltage terminal, and the input circuit includes a second transistor and a third transistor. A control electrode of the second transistor is coupled to the first clock signal terminal, a first electrode of the second transistor is coupled to the input terminal, and a second electrode of the second transistor is coupled to a third node; a control electrode of the third transistor is coupled to the first voltage terminal, a first electrode of the third transistor is coupled to the third node, and a second electrode of the third transistor is coupled to the first node. The first control circuit includes a fourth transistor, a control electrode of the fourth transistor is coupled to the first clock signal terminal, a first electrode of the fourth transistor is coupled to the first voltage terminal, and a second electrode of the fourth transistor is coupled to the second node. The first output circuit includes a fifth transistor and a first capacitor a control electrode of the fifth transistor is coupled to the first node, a first electrode of the fifth transistor is coupled to the second clock signal terminal, and a second electrode of the fifth transistor is coupled to the output terminal; and a first terminal of the first capacitor is coupled to the first node, and a second terminal of the first capacitor is coupled to the output terminal. The second output circuit includes a sixth transistor and a second capacitor; a control electrode of the sixth transistor is coupled to the second node, a first electrode of the sixth transistor is coupled to the second voltage terminal, and a second electrode of the sixth transistor is coupled to the output terminal; and a first terminal of the second capacitor is coupled to the second voltage terminal, and a second terminal of the second capacitor is coupled to the second node. The second control circuit includes a seventh transistor, a control electrode of the seventh transistor is coupled to the output terminal, a first electrode of the seventh transistor is coupled to the second voltage terminal, and a second electrode of the seventh transistor is coupled to the second node. The third control circuit includes an eighth transistor and a ninth transistor; a control electrode of the eighth transistor is coupled to the second node, and a first electrode of the eighth transistor is coupled to the second voltage terminal; and a control electrode of the ninth transistor is coupled to the second dock signal terminal, a first electrode of the ninth transistor is coupled to a second electrode of the eighth transistor, and a second electrode of the ninth transistor is coupled to the third node.

In another aspect, a gate driving circuit is provided. The gate driving circuit includes a plurality of shift registers. At least one of the plurality of shift registers is the shift register as described in any of the above embodiments.

In yet another aspect, a display apparatus is provided. The display apparatus includes the gate driving circuit described in the above embodiments.

In yet another aspect, a driving method of a shift register is provided. The shift register is the shift register described in any of the above embodiments. The driving method includes: transmitting, by the input circuit, the input signal received at the input terminal to the first node in response to the first clock signal received at the first clock signal terminal; transmitting, by the first control circuit, the first voltage of the first voltage terminal to the second node in response to the first clock signal received at the first clock signal terminal; transmitting, by the first output circuit, the second clock signal received at the second clock signal terminal to the output terminal in response to the voltage of the first node; and transmitting, by the second output circuit, the second voltage of the second voltage terminal to the output terminal in response to the voltage of the second node.

In some embodiments, the input circuit includes a first input sub-circuit and a second input sub-circuit; and transmitting, by the input circuit, the input signal received at the input terminal to the first node in response to the first clock signal received at the first clock signal terminal includes: transmitting, by the first input sub-circuit, the input signal in response to the first clock signal; and transmitting, by the second input sub-circuit, the input signal to the first node in response to the first voltage of the first voltage terminal.

### BRIEF DESCRIPTION OF THE DRAWINGS

In order to describe technical solutions in the present disclosure more clearly, accompanying drawings to be used in some embodiments of the present disclosure will be introduced briefly below. However, the accompanying drawings to be described below are merely accompanying drawings of some embodiments of the present disclosure, and a person of ordinary skill in the art may obtain other drawings according to these drawings. In addition, accompanying drawings in the following description may be regarded as schematic diagrams, and are not limitations on actual sizes of products, actual processes of methods, and actual timings of signals involved in the embodiments of the present disclosure.

FIG. 1 is a schematic diagram of a display apparatus, in accordance with some embodiments;

FIG. 2 is a schematic diagram of a display panel, in accordance with some embodiments;

FIG. 3 is a block diagram of a shift register, in accordance with some embodiments;

FIG. 4 is a block diagram of another shift register, in accordance with some embodiments;

FIG. 5 is a block diagram of yet another shift register, in accordance with some embodiments;

FIG. 6 is a block diagram of yet another shift register, in accordance with some embodiments;

FIG. 7 is a block diagram of yet another shift register, in accordance with some embodiments;

FIG. 8 is a circuit diagram of a shift register, in accordance with some embodiments;

FIG. 9 is a circuit diagram of another shift register, in accordance with some embodiments;

FIG. 10 is a circuit diagram of yet another shift register, in accordance with some embodiments;

FIG. 11 is a circuit diagram of yet another shift register, in accordance with some embodiments; and

FIG. 12 is a timing diagram of a shift register, in accordance with some embodiments.

### DETAILED DESCRIPTION

Technical solutions in some embodiments of the present disclosure will be described clearly and completely below with reference to the accompanying drawings. However, the described embodiments are merely some but not all of embodiments of the present disclosure. All other embodiments obtained on a basis of the embodiments of the present disclosure by a person of ordinary skill in the art shall be included in the protection scope of the present disclosure.

Unless the context requires otherwise, throughout the description and the claims, the term “comprise” and other forms thereof such as the third-person singular form “comprises” and the present participle form “comprising” are construed as open and inclusive meaning, i.e., “including, but not limited to.” In the description of the specification, the terms such as “one embodiment,” “some embodiments,” “exemplary embodiments,” “example,” “specific example,” or “some examples” are intended to indicate that specific features, structures, materials, or characteristics related to the embodiment(s) or example(s) are included in at least one embodiment or example of the present disclosure. Schematic representations of the above terms do not necessarily refer to the same embodiment(s) or example(s). In addition, the specific features, structures, materials, or characteristics may be included in any one or more embodiments or examples in any suitable manner.

Hereinafter, the terms “first” and “second” are used for descriptive purposes only, and are not to be construed as indicating or implying the relative importance or implicitly indicating the number of indicated technical features. Thus, a feature defined with “first” or “second” may explicitly or implicitly include one or more of the features. In the description of the embodiments of the present disclosure, “a plurality of,” “the plurality of,” or “multiple” means two or more unless otherwise specified.

In the description of some embodiments, the terms “coupled”, “connected” and derivatives thereof may be used. For example, the term “connected” may be used in the description of some embodiments to indicate that two or more components are in direct physical or electrical contact with each other. For another example, the term “coupled” may be used in the description of some embodiments to indicate that two or more components are in direct physical or electrical contact. However, the term “coupled” may also mean that two or more components are not in direct contact with each other, but still cooperate or interact with each other. The embodiments disclosed herein are not necessarily limited to the content herein.

The use of “configured to” herein means an open and inclusive expression, which does not exclude devices that are applicable to or configured to perform additional tasks or steps.

Some embodiments of the present disclosure provide a display apparatus. For example, the display apparatus may be any apparatus that displays an image whether in motion (e.g., a video) or stationary (e.g., a still image), and regardless of literal or graphical. More precisely, the display apparatus may be one of a plurality of electronic devices, the described embodiments may be implemented in or associated with a variety of electronic devices. The variety of electronic devices may include (but are not limited to), for example, mobile phones, wireless devices, personal data assistants (PDAs), hand-held or portable computers, global positioning system (GPS) receivers/navigators, cameras, MPEG-4 Part 14 (MP4) video players, video cameras, game consoles, watches, clocks, calculators, television monitors, flat panel displays, computer monitors, car displays (e.g., odometer displays), navigators, cockpit controllors and/or displays, camera-view displays (e.g., a rear view camera display in a vehicle), electronic photos, electronic billboards or signages, projectors, architectural structures, packagings and aesthetic structures (e.g., a display for displaying an image of a piece of jewelry). Embodiments of the present disclosure do not particularly limit a specific form of the display apparatus.

For example, the display apparatus is a display apparatus including current-driven type light-emitting devices, such as organic light-emitting diodes (OLEDs), light-emitting diodes (LEDs), micro light-emitting diodes (micro LEDs), mini light-emitting diodes (mini LEDs), or quantum light-emitting diodes (QLEDs). The current-driven type light-emitting devices are increasingly used in the field of high-performance displays due to their self-luminescence, fast response, wide viewing angle, and capability of being fabricated on a flexible substrate.

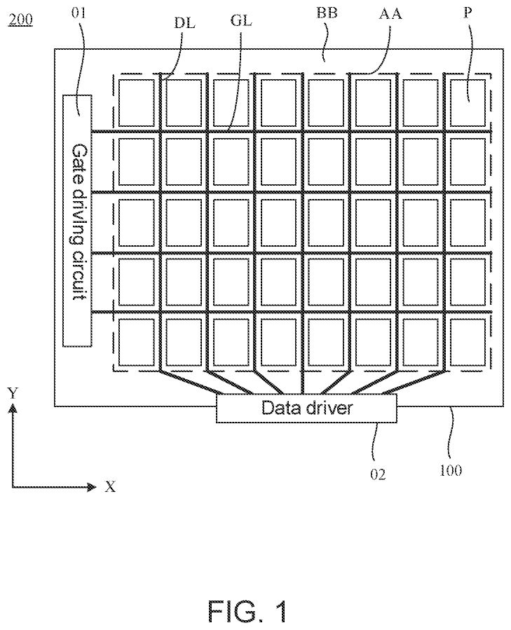

In some embodiments, as shown in FIG. 1, the display apparatus 200 includes a display panel 100. The display panel includes the current-driven type light-emitting devices.

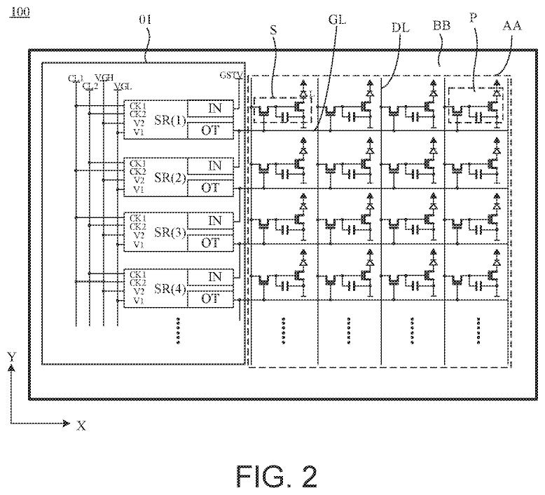

As shown in FIGS. 1 and 2, the display panel 100 has a display region AA and a peripheral region BB located on at least one side of the display region AA. For example, the peripheral region BB surrounds the display region AA.

As shown in FIGS. 1 and 2, the display panel 100 includes a plurality of sub-pixels P disposed in the display region AA. As shown in FIG. 2, at least one sub-pixel P (e.g., each sub-pixel P) includes a pixel circuit S and a light-emitting device L. The pixel circuit S is coupled to the light-emitting device L, and is configured to output a driving signal to the light-emitting device L, so as to drive the light-emitting device L to emit light.

For example, the light-emitting device L is a current-driven type light-emitting device.

It will be noted that an arrangement of the plurality of sub-pixels P may be designed according to actual conditions, and will not be limited herein. For example, as shown in FIGS. 1 and 2, the plurality of sub-pixels P are arranged in an array. In this case, sub-pixels P arranged in a line in a first direction X are referred to as a row of sub-pixels, and sub-pixels P arranged in a line in a second direction Y are referred to as a column of sub-pixels. The first direction X crosses the second direction Y. For example, the first direction X is perpendicular to the second direction Y.

Moreover, the specific structure of the pixel circuit is not limited in the embodiments of the present disclosure, which may be designed according to actual conditions. The pixel circuit may be composed of transistors (e.g., thin film transistors (TFTs)) and capacitor(s). In some examples, the pixel circuit includes two transistors (including a single switching transistor and a single driving transistor) and a capacitor, which form a 2T1C structure. In some other examples, the pixel circuit includes more than two transistors (including at least two switching transistors and a single driving transistor) and at least one capacitor. For example, the pixel circuit includes seven transistors and a single capacitor, which form a 7T1C structure.

In some embodiments, as shown in FIGS. 1 and 2, the display panel 100 is further includes a plurality of gate lines GL and a plurality of data lines DL located in the display region AA. For example, the plurality of gate lines GL extend in the first direction X, and the plurality of data lines DL extend in the second direction Y. For example, pixel circuits S in a row of sub-pixels P are coupled to a single gate line GL, and pixel circuits S in a column of sub-pixels P are coupled to a single data line DL.

In some embodiments, as shown in FIGS. 1 and 2, the display panel 100 further includes a gate driving circuit 01 located in the peripheral region BB. The gate driving circuit 01 is coupled to the plurality of gate lines GL, and is configured to provide scan signals to the plurality of gate lines GL.

The gate driving circuit 01 is arranged on a base substrate in the display panel 100 by adopting the GOA technique, so as to reduce the bezel width of the display apparatus 200.

It will be noted that the driving manner of the gate driving circuit 01 is not specifically limited in the embodiments of the present disclosure. For example, as shown in FIGS. 1 and 2, single-sided driving manner is adopted. That is, a gate driving circuit 01 is disposed on one side of the display region AA, and all the sub-pixels P are driven from the side of the display region AA. For another example, double-sided simultaneous driving manner is adopted. That is, two gate driving circuits 01 are disposed on two sides of the display region AA along an extending direction of signal lines (e.g., the gate lines) for transmitting scan signals, and each row of sub-pixels are driven from two sides of display region AA through the two gate driving circuits 01, simultaneously. For yet another example, double-sided alternate driving manner is adopted. That is, two gate driving circuits 01 are disposed on two sides of the display region AA along an extending direction of signal lines (e.g., the gate lines) for transmitting scan signals, the gate lines are divided into two groups (e.g., odd-numbered gate lines constitute one group, and even-numbered gate lines constitute the other group), and the two groups gate lines are respectively connected to the two gate driving circuits 01; a row of sub-pixels connected one of the gate lines in the one group and a row of sub-pixels connected one of the gate lines in the other group are alternately driven from two sides of display region AA through the two gate driving circuits 01.

In some embodiments, as shown in FIG. 1, the display apparatus 200 further includes a data driver 02. The data driver 02 is bonded to the peripheral region BB of the display panel 100. The data driver 02 is coupled to the plurality of data lines DL, and is configured to provide data signals to the plurality of data lines DL.

For example, the data driver 02 is a source driver IC.

In some embodiments, as shown in FIG. 2, the gate driving circuit 01 includes a plurality of shift registers SR (e.g., SR(1), SR(2), SR(3) . . . ). A shift register SR may be coupled to a single gate line GL, and the shift register SR is configured to output a scan signal to the gate line GL. In this case, the pixel circuit S coupled to the gate line GL may receive, a data signal from the data line DL coupled to the pixel circuit S when the scan signal is applied to the gate line GL, so as to output a driving signal to the light-emitting device L.

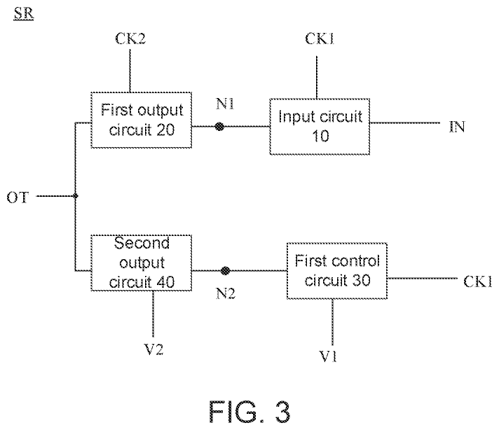

As shown in FIGS. 3 to 7, for at least one of the plurality of shift registers SR in the gate driving circuit 01 provided in the embodiments of the present disclosure, the shift register SR includes an input circuit 10, a first output circuit 20, a first control circuit 30, and a second output circuit 40.

The input circuit 10 is coupled to a first clock signal terminal CK1, a first node N1 and an input terminal IN. The first control circuit 30 is coupled to the first clock signal terminal CK1, a first voltage terminal V1 and a second node N2. The first output circuit 20 is coupled to the first node N1, a second clock signal terminal CK2 and an output terminal OT. The second output circuit 40 is coupled to the second node N2, a second voltage terminal V2 and the output terminal OT.

The input circuit 10 is configured to transmit an input signal received at the input terminal IN to the first node N1, in response to a first clock signal received at the first clock signal terminal CK1. The first control circuit 30 is configured to transmit a first voltage of the first voltage terminal V1 to the second node N2, in response to the first clock signal received at the first clock signal terminal CK1. The first output circuit 20 is configured to transmit a second clock signal received at the second clock signal terminal CK2 to the output terminal OT, in response to a voltage of the first node N1. The second output circuit 40 is configured to transmit a second voltage of the second voltage terminal V2 to the output terminal OT, in response to the voltage (i.e., the first voltage) of the second node N2.

In some examples, the first voltage of the first voltage terminal V1 is a direct current (DC) voltage, for example, a low-level DC voltage. The low-level voltage may be lower than a grounding voltage. The second voltage of the second voltage terminal V2 is a DC voltage, for example, a high-level DC voltage. The high-level voltage may be higher than the grounding voltage.

For example, there is a phase difference of 180 degrees between the first clock signal and the second clock signal. That is, at a same time, when the first clock signal is at a high level, the second clock signal is at a low level; and when the first clock signal is at a low level, the second clock signal is at a high level.

In some examples, if the first control circuit 30 is coupled to the input circuit 10, the first control circuit 30 only starts to operate in response to the input signal input by the input circuit 10. That is, the input circuit 10 drives the first control circuit 30 to operate. As a result, a driving load of the input circuit 10 is increased, and size(s) of circuit element(s) (e.g., transistor(s)) in the input circuit 10 may be increased, which is not conducive to the realization of a narrow bezel of the display apparatus 200.

However, in the shift register SR provided in the embodiments of the present disclosure, the input circuit 10 is not coupled to the first control circuit 30, and the first control circuit 30 starts to operate in response to the first clock signal received at the first clock signal terminal CK1, which has no relation with whether the input circuit 10 is turned on. That is, the input circuit 10 does not drive the first control circuit 30 to operate. In this case, the driving load of the input circuit 10 may be reduced, and the size(s) of the circuit element(s) (e.g., transistor(s)) in the input circuit 10 may be reduced. As a result, a size of the shift register SR may be reduced, which facilitates the realization of the narrow bezel of the display apparatus 200.

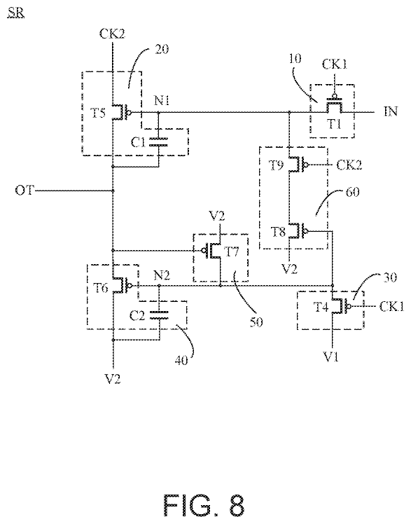

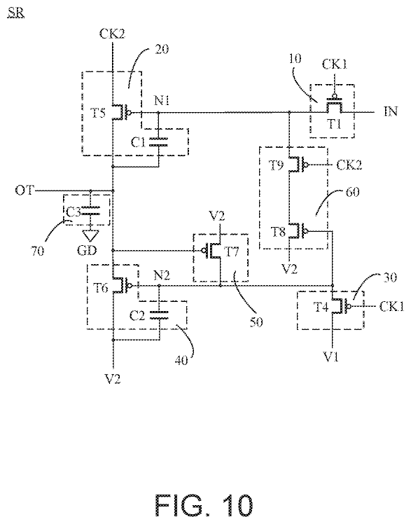

In some examples, as shown in FIGS. 8 and 10, the input circuit 10 includes a first transistor T1. A control electrode of the first transistor T1 is coupled to the first clock signal terminal CK1, a first electrode of the first transistor T1 is coupled to the input terminal IN, and a second electrode of the first transistor T1 is coupled to the first node N1. In this case, since the first transistor T1 is not used for driving the first control circuit 30 to operate, a driving load of the first transistor T1 is reduced, and further a size of the first transistor T1 is reduced. As a result, the size of the shift register SR is reduced, which facilitates the realization of the narrow bezel of the display apparatus 200.

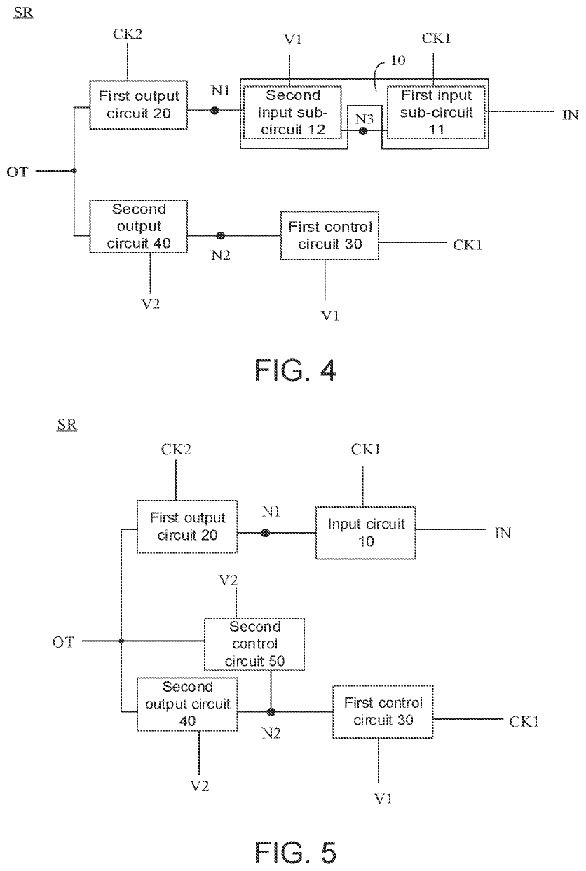

In some embodiments, as shown in FIGS. 4, 6, and 7, the input circuit 10 is further coupled to the first voltage terminal V1. The input circuit 10 is configured to transmit the input signal received at the input terminal IN to the first node N1, in response to the first clock signal received at the first clock signal terminal CK1 and the first voltage of the first voltage terminal V1.

In some embodiments, as shown in FIGS. 4, 6, and 7, the input circuit 10 includes a first input sub-circuit 11 and a second input sub-circuit 12. The first input sub-circuit 11 is coupled to the first clock signal terminal CK1, the input terminal IN and a third node N3. The second input sub-circuit 12 is coupled to the third node N3, the first voltage terminal V1 and the first node N1. The first input sub-circuit 11 is configured to transmit the input signal to the third node N3, in response to the first clock signal. The second input sub-circuit 12 is configured to connect the first input sub-circuit 11 to the first node N1 in response to the first voltage of the first voltage terminal V1, so as to transmit the input signal at the third node N3 to the first node N1.

In this case, the first input sub-circuit 11 and the first node N1 are connected through the second input sub-circuit 12, which may avoid the influence of circuit element(s) in the first input sub-circuit 11 on stability of the voltage of the first node N1.

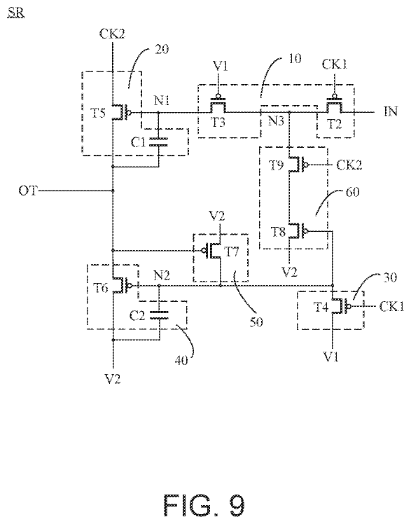

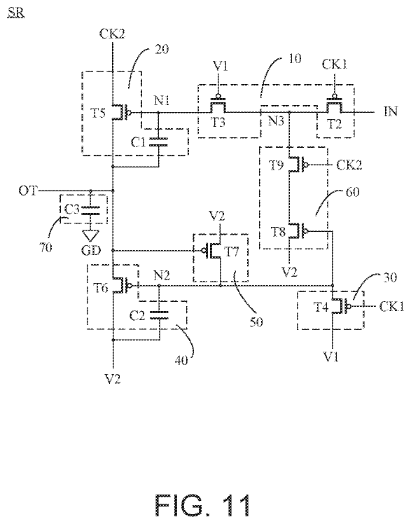

In some examples, as shown in FIGS. 9 and 11, the first input sub-circuit 11 includes a second transistor T2. A control electrode of the second transistor T2 is coupled to the first clock signal terminal CK1, a first electrode of the second transistor T2 is coupled to the input terminal IN, and a second electrode of the second transistor T2 is coupled to the third node N3. The second input sub-circuit 12 includes a third transistor T3. A control electrode of the third transistor T3 is coupled to the first voltage terminal V1, a first electrode of the third transistor T3 is coupled to the third node N3, and a second electrode of the third transistor T3 is coupled to the first node N1.

When the third transistor T3 is turned off, the second transistor T2 and the first node N1 do not form a conductive path, and thus a leakage current of the second transistor T2 does not pass through the first node N1, which avoids an influence of the leakage current of the second transistor T2 on the stability of the voltage of the first node N1.

In some examples, as shown in FIGS. 8 to 11, the first control circuit 30 includes a fourth transistor T4. A control electrode of the fourth transistor T4 is coupled to the first clock signal terminal CK1, a first electrode of the fourth transistor T4 is coupled to the first voltage terminal V1, and a second electrode of the fourth transistor T4 is coupled to the second node N2.

In some examples, as shown in FIGS. 8 to 11, the first output circuit 20 includes a fifth transistor T5 and a first capacitor C1. A control electrode of the fifth transistor T5 is coupled to the first node N1, a first electrode of the fifth transistor T5 is coupled to the second clock signal terminal CK2, and a second electrode of the fifth transistor T5 is coupled to the output terminal OT. A first terminal of the first capacitor C1 is coupled to the first node N1, and a second terminal of the first capacitor C1 is coupled to the output terminal OT.

In some examples, as shown in FIGS. 8 to 11, the second output circuit 40 includes a sixth transistor T6 and a second capacitor C2. A control electrode of the sixth transistor T6 is coupled to the second node N2, a first electrode of the sixth transistor T6 is coupled to the second voltage terminal V2, and a second electrode of the sixth transistor T6 is coupled to the output terminal OT. A first terminal of the second capacitor C2 is coupled to the second voltage terminal V2, and a second terminal of the second capacitor C2 is coupled to the second node N2.

In some embodiments, as shown in FIGS. 5 to 7, the shift register SR further includes a second control circuit 50. The second control circuit 50 is coupled to the second node N2, the second voltage terminal V2 and the output terminal OT. The second control circuit 50 is configured to transmit the second voltage of the second voltage terminal V2 to the second node N2, in response to the output signal at the output terminal OT.

In some examples, as shown in FIGS. 8 to 11, the second control circuit 50 includes a seventh transistor T7. A control electrode of the seventh transistor T7 is coupled to the output terminal OT, a first electrode of the seventh transistor T7 is coupled to the second voltage terminal V2, and a second electrode of the seventh transistor T7 is coupled to the second node N2.

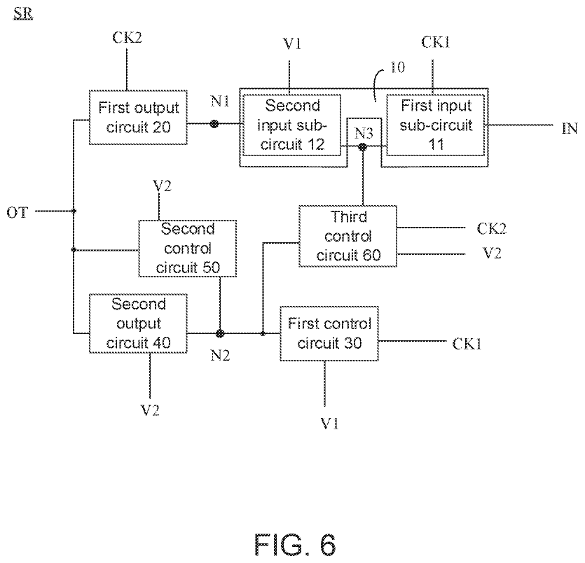

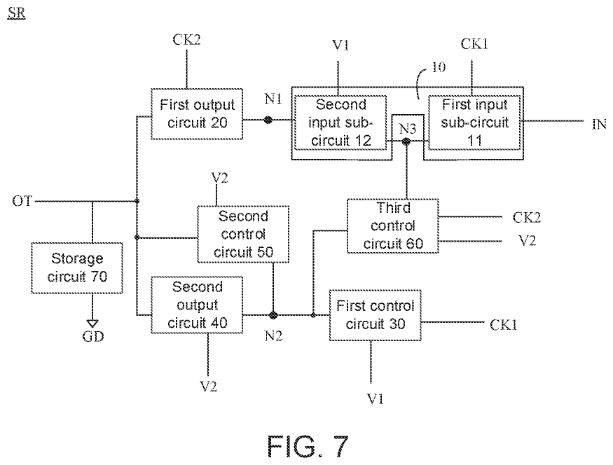

In some embodiments, as shown in FIGS. 6 and 7, the shift register SR further includes a third control circuit 60. The third control circuit 60 is coupled to the second clock signal terminal CK2, the second voltage terminal V2, the second node N2 and the third node N3. The third control circuit 60 is configured to transmit the second voltage of the second voltage terminal V2 to the third node N3, in response to the voltage (i.e., the first voltage) of the second node N2 and the second clock signal received at the second clock signal terminal CK2, so as to control a voltage of the third node N3.

In some examples, as shown in FIGS. 8 to 11, the third control circuit 60 includes an eighth transistor T8 and a ninth transistor T9. A control electrode of the eighth transistor T8 is coupled to the second node N2, and a first electrode of the eighth transistor T8 is coupled to the second voltage terminal V2. A control electrode of the ninth transistor T9 is coupled to the second clock signal terminal CK2, and a first electrode of the ninth transistor T9 is coupled to a second electrode of the eighth transistor T8. For example, as shown in FIGS. 9 and 11, a second electrode of the ninth transistor T9 is coupled to the third node N3. For another example, as shown in FIGS. 8 and 10, the second electrode of the ninth transistor T9 is coupled to the first node N1.

Structures of the shift register SR will be described below. As shown in FIG. 6, the shift register SR includes the input circuit 10, the first control circuit 30, the first output circuit 20, the second output circuit 40, the second control circuit 50 and the third control circuit 60.

In some examples, as shown in FIGS. 8 and 10, the input circuit 10 includes a first transistor T1. The first control circuit 30 includes a fourth transistor T4. The first output circuit 20 includes a fifth transistor T5 and a first capacitor C1. The second output circuit 40 includes a sixth transistor T6 and a second capacitor C2. The second control circuit 50 includes a seventh transistor T7. The third control circuit 60 includes an eighth transistor T8 and a ninth transistor T9.

A control electrode of the first transistor T1 is coupled to the first clock signal terminal CK1, a first electrode of the first transistor T1 is coupled to the input terminal IN, and a second electrode of the first transistor T1 is coupled to the first node N1.

A control electrode of the fourth transistor T4 is coupled to the first clock signal terminal CK1, a first electrode of the fourth transistor T4 is coupled to the first voltage terminal V1, and a second electrode of the fourth transistor T4 is coupled to the second node N2.

A control electrode of the fifth transistor T5 is coupled to the first node N1, a first electrode of the fifth transistor T5 is coupled to the second clock signal terminal CK2, and a second electrode of the fifth transistor T5 is coupled to the output terminal OT. A first terminal of the first capacitor C1 is coupled to the first node N1, and a second terminal of the first capacitor C1 is coupled to the output terminal OT.

A control electrode of the sixth transistor T6 is coupled to the second node N2, a first electrode of the sixth transistor T6 is coupled to the second voltage terminal V2, and a second electrode of the sixth transistor T6 is coupled to the output terminal OT. A first terminal of the second capacitor C2 is coupled to the second voltage terminal V2, and a second terminal of the second capacitor C2 is coupled to the second node N2.

A control electrode of the seventh transistor T7 is coupled to the output terminal OT, a first electrode of the seventh transistor T7 is coupled to the second voltage terminal V2, and a second electrode of the seventh transistor T7 is coupled to the second node N2.

A control electrode of the eighth transistor T8 is coupled to the second node N2, and a first electrode of the eighth transistor T8 is coupled to the second voltage terminal V2. A control electrode of the ninth transistor T9 is coupled to the second clock signal terminal CK2, a first electrode of the ninth transistor T9 is coupled to a second electrode of the eighth transistor T8, and a second electrode of the ninth transistor T9 is coupled to the third node N3.

In some other examples, as shown in FIGS. 9 and 11, the input circuit 10 includes a second transistor T2 and a third transistor T3. The first control circuit 30 includes a fourth transistor T4. The first output circuit 20 includes a fifth transistor T5 and a first capacitor C1. The second output circuit 40 includes a sixth transistor T6 and a second capacitor C2. The second control circuit 50 includes a seventh transistor T7. The third control circuit 60 includes an eighth transistor T8 and a ninth transistor T9.

A control electrode of the second transistor T2 is coupled to the first clock signal terminal CK1, a first electrode of the second transistor T2 is coupled to the input terminal IN, and a second electrode of the second transistor T2 is coupled to the third node N3. A control electrode of the third transistor T3 is coupled to the first voltage terminal V1, a first electrode of the third transistor T3 is coupled to the third node N3, and a second electrode of the third transistor T3 is coupled to the first node N1.

It will be noted that, as for the coupling manners of the fourth transistor T4, the fifth transistor T5, the first capacitor C1, the sixth transistor T6, the second capacitor C2, the seventh transistor T7, the eighth transistor T8, and the ninth transistor T9, reference may be made to the above corresponding descriptions, and details will not be repeated here.

In some embodiments, as shown in FIG. 7, the shift register SR further includes a storage circuit 70. The storage circuit 70 is coupled to the output terminal OT and a fixed voltage terminal GD. The storage circuit 70 is configured to store the output signal at the output terminal OT. In this case, the storage circuit 70 may store the output signal at the output terminal OT to improve stability of a voltage of the output signal at the output terminal OT.

In some examples, as shown in FIGS. 10 and 11, the storage circuit 70 includes a third capacitor C3. A first terminal of the third capacitor C3 is coupled to the output terminal OT, and a second terminal of the third capacitor C3 is coupled to the fixed voltage terminal GD. The fixed voltage terminal GD is configured to transmit a fixed voltage signal. The fixed voltage signal may be a DC voltage signal. For example, the fixed voltage signal is the grounding signal. That is, the fixed voltage terminal GD may be a grounding terminal.

It will be noted that, the transistors used in the shift register SR provided in the embodiments of the present disclosure may be thin film transistors (TFTs), field effect transistors (FETs), or other switching devices with the same characteristics, which is not limited in the embodiments of the present disclosure.

In some embodiments, a control electrode of each transistor used in the shift register SR is a gate of the transistor, a first electrode is one of a source and a drain of the transistor, and a second electrode is the other of the source and the drain of the transistor. Since the source and the drain of the transistor may be symmetrical in structure, there may be no difference in structure between the source and the drain of the transistor. That is, the first electrode and the second electrode of the transistor in the embodiments of the present disclosure may be the same in structure. For example, in a case where the transistor is a P-type transistor, the first electrode of the transistor is the source, and the second electrode thereof is the drain. For example, in a case where the transistor is an N-type transistor, the first electrode of the transistor is the drain, and the second electrode thereof is the source.

In the embodiments of the present disclosure, each of a plurality of terminals (e.g., including the input terminal, the output terminal, the first clock signal terminal, the second clock signal terminal, the first voltage terminal, and the second voltage terminal) is a connection point between the circuit and a corresponding signal line. Each terminal may be a node of relevant electrical connection between the circuit and the corresponding signal line in a circuit diagram, that is, the terminal is equivalent to a node of relevant connection between the circuit and the corresponding signal line in the circuit diagram.

In the embodiments of the present disclosure, the nodes (e.g., the first node N1, the second node N2, and the third node N3) do not represent actual components, but rather represent junctions of related electrical connections in the circuit diagram. That is, these nodes are equivalent to the junctions of the related electrical connections in the circuit diagram.

In the embodiments of the present disclosure, specific implementation manners of the input circuit 10, the first output circuit 20, the first control circuit 30, the second output circuit 40, the second control circuit 50, the third control circuit 60, and the storage circuit 70 are not limited to the manners described above, and may be any implementation manners, as long as corresponding functions may be achieved. The above embodiments/examples do not limit the protection scope of the present disclosure. In practical applications, a person skilled in art may choose to use or not to use one or more of the above circuits according to situations. Various combinations and variations based on the above circuits do not depart from the principle of the present disclosure, and details will not be repeated herein.

In the circuit provided in the embodiments of the present disclosure, in addition to the first transistor T1, the second transistor T2, the third transistor T3, the fourth transistor T4, the fifth transistor T5, the sixth transistor T6, the seventh transistor T7, the eighth transistor T8, and the ninth transistor T9, the circuit may further include other transistors, at least one of which constitutes a parallel structure with the one of the above nine transistors. The first transistor T1 is taken as an example, a control electrode of the at least one transistor and the control electrode of the first transistor T1 are coupled to the same terminal (e.g., to receive the same signal), a first electrode of the at least one transistor and the first electrode of the first transistor T1 are coupled to the same signal terminal (e.g., to receive or transmit the same signal), and a second electrode of the at least one transistor and the second electrode of the first transistor T1 are coupled to the same terminal (e.g., to receive or transmit the same signal).

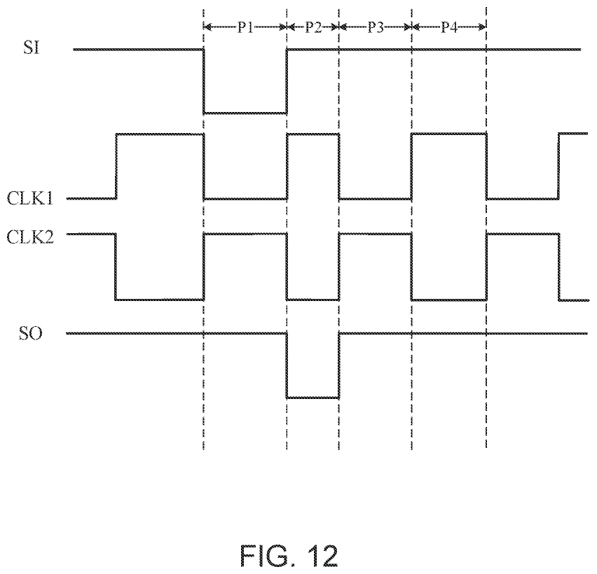

An operating process of the shift register SR will be described below by taking an example in which each transistor in the shift register SR is a P-type transistor. As shown in FIG. 12, an operating period of the shift register SR within a single frame may include a first period P1, a second period P2, a third period P3, and a fourth period P4. For example, the first voltage of the first voltage terminal V1 is at a low level, and the second voltage of the second voltage terminal V2 is at a high level.

As shown in FIG. 12, in the first period P1, the input signal SI received at the input terminal IN is at a low level, the first clock signal CLK1 received at the first clock signal terminal CK1 is at a low level, and the second clock signal CLK2 received at the second clock signal terminal CK2 is at a high level.

In some examples, as shown in FIGS. 3 and 5, the input circuit 10 transmits the input signal SI received at the input terminal IN to the first node N1 in response to the first clock signal CLK1 received at the first clock signal terminal CK1. For example, as shown in FIGS. 8 and 10, the first transistor T1 in the input circuit 10 is turned on in response to the low-level voltage of the first clock signal CLK1, and transmits the low-level voltage of the input signal SI to the first node N1. In this case, the voltage of the first node N1 is at a low level.

In some other examples, as shown in FIGS. 4, 6, and 7, the input circuit 10 inputs the input signal SI in response to the first clock signal CLK1, and transmits the input signal SI to the first node N1 in response to the first voltage of the first voltage terminal V1. That is, the first input sub-circuit 11 transmits the input signal SI to the third node N3 in response to the first clock signal CLK1, and the second input sub-circuit 12 transmits the input signal SI to the first node N1 in response to the first voltage. For example, as shown in FIGS. 9 and 11, the second transistor T2 is turned on in response to the low-level voltage of the first clock signal CLK1, and transmits the low-level voltage of the input signal SI to the third node N3, and the third transistor T3 is turned on in response to the low-level first voltage, and transmits the low-level voltage of the input signal SI to the first node N1. In this case, the voltage of the first node N1 is at a low level.

As shown in FIGS. 3 to 7, the first output circuit 20 transmits the second clock signal CLK2 received at the second clock signal terminal CK2 to the output terminal OT in response to the voltage of the first node N1. For example, as shown in FIGS. 8 to 11, the fifth transistor T5 is turned on in response to the low-level voltage of the first node N1, and transmits the high-level voltage of the second clock signal CLK2 to the output terminal OT. In this case, the output signal SO at the output terminal OT is at a high level.

As shown in FIGS. 3 to 7, the first control circuit 30 transmits the first voltage of the first voltage terminal V1 to the second node N2 in response to the first clock signal CLK1. For example, as shown in FIGS. 8 to 11, the fourth transistor T4 is turned on in response to the low-level voltage of first clock signal CLK1, and transmits the low-level first voltage to the second node N2. In this case, the voltage of the second node N2 is at a low level.

As shown in FIGS. 3 to 7, the second output circuit 40 transmits the second voltage of the second voltage terminal V2 to the output terminal OT in response to the voltage of the second node N2. For example, as shown in FIGS. 8 to 11, the sixth transistor T6 is turned on in response to the low-level voltage of the second node N2, and transmits the high-level second voltage to the output terminal OT. In this case, the output signal SO at the output terminal OT is at a high level.

Since the output signal SO is at the high level, the seventh transistor T7 in the second control circuit 50 is turned off, and will not transmit the high-level second voltage to the second node N2, so that the voltage of the second node N2 can maintain the low level.

In the third control circuit 60, the eighth transistor T8 is turned on in response to the low-level voltage of the second node N2, and transmits the high-level second voltage to the first electrode of the ninth transistor T9. The ninth transistor T9 is turned off and will not transmit the high-level second voltage to the third node N3. In this way, the first node N1 can maintain the low-level voltage.

Therefore, in the first period P1, the output signal SO at the output terminal OT is at the high level. The high-level voltage of the second clock signal CLK2 is equal to the second voltage, and thus the high-level voltage of the output signal SO is equal to the high-level voltage of the second clock signal CLK2 and the second voltage.

As shown in FIG. 12, in the second period P2, the input signal SI received at the input terminal IN is at a high level, the first clock signal CLK1 received at the first clock signal terminal CK1 is at a high level, and the second clock signal CLK2 received at the second clock signal terminal CK2 is at a low level.

The input terminal IN and the first node N1 can not form a conductive path under the control of the input circuit 10. In some examples, as shown in FIGS. 8 and 10, the first transistor T1 in the input circuit 10 is turned off, and will not transmit the high-level voltage of the input signal SI to the first node N1. In some other examples, as shown in FIGS. 9 and 11, the second transistor T2 is turned off, and will not transmit the high-level voltage of the input signal SI to the third transistor T3.

In the first output circuit 20, due to the coupling effect of the first capacitor C1, the voltage of the first node N1 can maintain the low level in the previous period (i.e., the first period P1). The fifth transistor T5 is turned on in response to the low-level voltage of the first node N1, and transmits the low-level voltage of the second clock signal CLK2 received at the second clock signal terminal CK2 to the output terminal OT.

Referring to FIGS. 9 and 11, when the output signal SO changes from the high-level voltage to the low-level voltage, due to the coupling effect of the first capacitor C1, the low-level voltage of the first node N1 in the second period P2 is lower than the low-level voltage of the first node N1 in the first period P1. The low-level voltage of the first node N1 is also lower than the first voltage of the first voltage terminal V1. In this case, the gate-source voltage difference of the third transistor T3 cannot ensure that the third transistor T3 is turned on, so that the third transistor T3 is turned off. For example, the voltage of the first node N1 is −10 V, that is, a source voltage of the third transistor T3 is −10 V; and the first voltage of the first voltage terminal V1 is −5 V, that is, a gate voltage of the third transistor T3 is −5 V. Based on this, the gate-source voltage difference of the third transistor T3 is 5 V. that is, the gate-source voltage difference of the third transistor T3 is positive. Since the third transistor T3 is a P-type transistor, the third transistor T3 is turned off. Therefore, the second transistor T2 and the first node N1 do not form a conductive path, and it is possible to avoid the influence of the leakage current of the second transistor T2 on the stability of the voltage of the first node N1.

Due to the high-level voltage of the first clock signal CLK1, the fourth transistor T4 in the first control circuit 30 is turned off, and will not transmit the low-level first voltage to the second node N2.

As shown in FIGS. 5 to 7, the second control circuit 50 transmits the second voltage of the second voltage terminal V2 to the second node N2 in response to the output signal SO at the output terminal OT. For example, as shown in FIGS. 8 to 11, the seventh transistor T7 is turned on in response to the low-level voltage of the output signal SO, and transmits the high-level second voltage to the second node N2. In this case, the voltage of the second node N2 is at a high level.

Since the voltage of the second node N2 is at the high level, the sixth transistor T6 in the second output circuit 40 is turned off, and the voltage of the output signal SO at the output terminal OT is the low-level voltage of the second clock signal CLK2 received at the second clock signal terminal CK2.

In the third control circuit 60, the ninth transistor T9 is turned on in response to the low-level voltage of the second clock signal CLK2, and the eighth transistor T8 is turned off. Therefore, the high-level second voltage will be transmitted to neither the third node N3 nor the first node N1, and the voltage of the first node N1 maintains the low level.

In addition, due to the coupling effect of the third capacitor C3 in the storage circuit 70, the stability of the voltage of the output signal SO at the output terminal OT may be improved, so that the voltage of the output terminal OT may be maintained.

Therefore, in the second period P2, the output signal SO at the output terminal OT is at the low level.

As shown in FIG. 12, in the third period P3, the input signal SI received at the input terminal IN is at a high level, the first clock signal CLK1 received at the first clock signal terminal CK1 is at a low level, and the second clock signal CLK2 at the second clock signal terminal CK2 is at a high level.

As shown in FIGS. 3 and 5, the input circuit 10 transmits the input signal SI received at the input terminal IN to the first node N1 in response to the first clock signal CLK1 received at the first clock signal terminal CK1. For example, as shown in FIGS. 8 and 10, the first transistor T1 in the input circuit 10 is turned on in response to the low-level voltage of the first clock signal CLK1, and transmits the high-level voltage of the input signal SI to the first node N1. In this case, the voltage of the first node N1 is at a high level.

In some other examples, as shown in FIGS. 4, 6, and 7, the input circuit 10 inputs the input signal SI in response to the first clock signal CLK1, and transmits the input signal SI to the first node N1 in response to the first voltage of the first voltage terminal V1. That is, the first input sub-circuit 11 transmits the input signal SI to the third node N3 in response to the first clock signal CLK1, and the second input sub-circuit 12 transmits the input signal SI to the first node N1 in response to the first voltage. For example, as shown in FIGS. 9 and 11, the second transistor T2 is turned on in response to the low-level voltage of the first clock signal CLK1, and transmits the high-level voltage of the input signal SI to the third node N3, and the third transistor T3 is turned on in response to the low-level first voltage, and transmits the high-level voltage of the input signal SI to the first node N1. In this case, the voltage of the first node N1 is at a high level.

As shown in FIGS. 8 to 11, the fifth transistor T5 is turned off, and will not transmit the high-level voltage of the second clock signal CLK2 to the output terminal OT.

As shown in FIGS. 3 to 7, the first control circuit 30 transmits the first voltage of the first voltage terminal V1 to the second node N2 in response to the first clock signal CLK1. For example, as shown in FIGS. 8 to 11, the fourth transistor T4 is turned on in response to the low-level voltage of the first clock signal CLK1, and transmits the low-level first voltage to the second node N2. In this case, the voltage of the second node N2 is at a low level.

As shown in FIGS. 3 to 7, the second output circuit 40 transmits the second voltage of the second voltage terminal V2 to the output terminal OT in response to the voltage of the second node N2. For example, as shown in FIGS. 8 to 11, the sixth transistor T6 is turned on in response to the low-level voltage of the second node N2, and transmits the high-level second voltage to the output terminal OT. In this case, the output signal SO at the output terminal OT is at a high level.

Since the output signal SO is at the high level, the seventh transistor T7 in the second control circuit 50 is turned off, and will not transmit the high-level second voltage to the second node N2, so that the voltage of the second node N2 can maintain the low level.

In the third control circuit 60, the eighth transistor T8 is turned on in response to the low-level voltage of the second node N2, and transmits the high-level second voltage of the second voltage terminal V2 to the first electrode of the ninth transistor T9. The ninth transistor T9 is turned off, and will not transmit the high-level second voltage to the third node N3.

Therefore, in the third period P3, the output signal SO at the output terminal OT is at the high level.

As shown in FIG. 12, in the fourth period P4, the input signal SI is at a high level, the first clock signal CLK1 is at a high level, and the second clock signal CLK2 is at a low level.

The input terminal IN and the first node N1 can not form a conductive path under the control of the input circuit 10. In some examples, as shown in FIGS. 8 and 10, the first transistor T1 in the input circuit 10 is turned off, and will not transmit the high-level voltage of the input signal SI to the first node N1. In some other examples, as shown in FIGS. 9 and 11, the third transistor T3 is turned on in response to the low-level first voltage, and the second transistor T2 is turned off. Therefore, the high-level voltage of the input signal SI will not be transmitted to the first node N1.

In the first output circuit 20, due to the coupling effect of the first capacitor C1, the voltage of the first node N1 can maintain the high level in the previous period (i.e., the third period P3), and in this case, the fifth transistor T5 is turned off. Since the first clock signal CLK1 is at the high level, the fourth transistor T4 in the first control circuit 30 is turned off. In the second output circuit 40, due to the coupling effect of the second capacitor C2, the voltage of the second node N2 can maintain the low level in the previous period (i.e., the third period P3). In this case, the sixth transistor T6 is turned on in response to the low-level voltage of the second node N2, and transmits the high-level second voltage to the output terminal OT. Therefore, the output signal SO of the output terminal OT is at a high level.

In the third control circuit 60, the eighth transistor T8 is turned on in response to the low-level voltage of the second node N2, and transmits the high-level second voltage to the first electrode of the ninth transistor T9. The ninth transistor T9 is turned on in response to the low-level voltage of the second clock signal CLK2, and transmits the high-level second voltage to the third node N3. In this case, the voltage of the third node N3 is at a high level. The turned-on third transistor T3 may connect the first node N1 and the third node N3, and as a result, the voltage of the first node N1 is also at the high level.

In addition, since the output signal SO is at a high level, the seventh transistor T7 in the second control circuit 50 is turned off.

Therefore, in the fourth period P4, the output signal SO at the output terminal OT is at the high level.

In summary, in the shift register SR, the turning-on of the fourth transistor T4 in the first control circuit 30 is related to the first clock signal CLK1 received at the first clock signal terminal CK1, and is unrelated to whether the transistor(s) (for example, the first transistor T1; for another example, the second transistor T2 and the third transistor T3) in the input circuit 10 is turned on. That is, the fourth transistor T4 is not driven by the transistor(s) in the input circuit 10. In this way, the driving load of the transistor(s) in the input circuit 10 may be reduced, which is beneficial to reduce the size(s) of the transistor(s) in the input circuit 10. Therefore, the size of the shift register SR may be reduced, and further the bezel width of the display apparatus 200 may be reduced, which may be conducive to the realization of the narrow bezel of the display apparatus 200.

In some embodiments, as shown in FIG. 2, the display panel 100 further includes a start signal line GSTV. The start signal line GSTV is configured to provide a start signal. For example, in the plurality of shift registers SR in the gate driving circuit 01, an input terminal IN of a first shift register SR(1) may be coupled to the start signal line GSTV, and then an input signal received by an input circuit 10 of the first shift register SR(1) is the start signal.

For example, as shown in FIG. 2, except the first shift register SR(1), an input terminal IN of each shift register SR is coupled to an output terminal OT of a previous shift register SR. That is, except the first shift register SR(1), an input signal received by each shift register SR may be an output signal of the previous shift register SR.

In some embodiments, as shown in FIG. 2, the display panel 100 further includes a plurality of clock signal lines. The plurality of clock signal lines include first clock signal line(s) CL1 and second clock signal line(s) CL2. The first clock signal line CL1 is configured to provide a clock signal, and the second clock signal line CL2 is configured to provide another clock signal. There is a phase difference of 180 degrees between the clock signal provided by the first clock signal line CL1 and the another clock signal provided by the second clock signal line CL2.

In some examples, first clock signal terminals CK1 in any two adjacent cascaded shift registers SR are coupled to different clock signal lines, and second clock signal terminals CK2 in any two adjacent cascaded shift registers SR are coupled to different clock signal lines. For example, as shown in FIG. 2, first clock signal terminals CK1 of odd-number-stage shift registers SR (e.g., SR(1), SR(3), etc.) are coupled to the first clock signal line CL1, and second clock signal terminals CK2 of the odd-number-stage shift registers SR are coupled to the second clock signal line CL2; and first clock signal terminals CK1 of even-number-stage shift registers SR (e.g., SR(2), SR(4), etc.) are coupled to the second clock signal line CL2, and second clock signal terminals CK2 of the even-number-stage shift registers SR are coupled to the first clock signal line CL1. In this case, the clock signal received by the first clock signal terminals CK1 of the odd-number-stage shift registers SR from the first signal line CL1 serves as the first clock signal, and the another clock signal, received by the second clock signal terminals CK2 of the odd-number-stage shift registers SR from the second signal line CL2 serves as the second clock signal; and the another clock signal received by the first clock signal terminals CK1 of the even-number-stage shift registers SR from the second signal line CL2 serves as the first clock signal, and the clock signal received by the second clock signal terminals CK2 of the even-number-stage shift registers SR from the first signal line CL1 serves as the second clock signal.

It will be noted that in the embodiments of the present disclosure, manners of the shift registers connected in cascade in the gate driving circuit and manners of the shift registers connected to the clock signal lines are not limited, and may be the above manners or other manners.

In some embodiments, as shown in FIG. 2, the display panel 100 further includes a first voltage line VGL and a second voltage line VGH. The first voltage line VGL is configured to provide the first voltage, and the second voltage line VGH is configured to provide the second voltage. The first voltage terminal V1 of each shift register SR is coupled to the first voltage line VGL, and the second voltage terminal V2 thereof is coupled to the second voltage line VGH.

Some embodiments of the present disclosure provide a driving method of a shift register. The shift register is the shift register SR described in any of the above embodiments.

Referring to FIG. 3, the shift register SR includes the input circuit 10, the first control circuit 30, the first output circuit 20, and the second output circuit 40. The input circuit 10 is coupled to the first clock signal terminal CK1, the first node N1, and the input terminal IN. The first control circuit 30 is coupled to the first clock signal terminal CK1, the first voltage terminal V1, and the second node N2. The first output circuit 20 is coupled to the first node N1, the second clock signal terminal CK2, and the output terminal OT. The second output circuit 40 is coupled to the second node N2, the second voltage terminal V2, and the output terminal OT.

The driving method includes: transmitting, by the input circuit 10, the input signal received at the input terminal IN to the first node N1 in response to the first clock signal received at the first clock signal terminal CK1; transmitting, by the first control circuit 30, the first voltage of the first voltage terminal V1 to the second node N2 in response to the first clock signal received at the first clock signal terminal CK1; transmitting, by the first output circuit 20, the second clock signal received at the second clock signal terminal CK2 to the output terminal OT in response to the voltage of the first node N1; and transmitting, by the second output circuit 40, the second voltage of the second voltage terminal V2 to the output terminal OT in response to the voltage of the second node N2.

In some embodiments, referring to FIG. 4, the input circuit 10 includes the first input sub-circuit 11 and the second input sub-circuit 12. In this case, that transmitting, by the input circuit 10, the input signal received at the input terminal IN to the first node N1 in response to the first clock signal received at the first clock signal terminal CK1 includes: transmitting, by the first input sub-circuit 11, the input signal in response to the first clock signal; and transmitting, by the second input sub-circuit 12, the input signal to the first node N1 in response to the first voltage of the first voltage terminal V1.

It will be noted that the driving method of the shift register SR has the same beneficial effects as the shift register SR described above, and details will not be repeated here. In addition, the driving process of the shift register SR can refer to the above description of the operating process of the shift register SR, and details will not be repeated here.

The foregoing descriptions are merely specific implementations of the present disclosure, but the protection scope of the present disclosure is not limited thereto. Any person skilled in the art could conceive of changes or replacements within the technical scope of the present disclosure, which shall all be included in the protection scope of the present disclosure. Therefore, the protection scope of the present disclosure shall be subject to the protection scope of the claims.

What is claimed is:

1. A shift register, comprising:
an input circuit at least coupled to a first clock signal terminal, an input terminal and a first node, wherein the input circuit is configured to transmit an input signal received at the input terminal to the first node in response to a first clock signal received at the first clock signal terminal;
a first control circuit coupled to the first clock signal terminal, a first voltage terminal and a second node, wherein the first control circuit is configured to transmit a first voltage of the first voltage terminal to the second node in response to the first clock signal received at the first clock signal terminal;
a first output circuit coupled to the first node, a second clock signal terminal and an output terminal, wherein the first output circuit is configured to transmit a second clock signal received at the second clock signal terminal to the output terminal in response to a voltage of the first node; and
a second output circuit coupled to the second node, a second voltage terminal and the output terminal, wherein the second output circuit is configured to transmit a second voltage of the second voltage terminal to the output terminal in response to a voltage of the second node.

2. The shift register according to claim 1, wherein the input circuit includes a first transistor, and a control electrode of the first transistor is coupled to the first clock signal terminal, a first electrode of the first transistor is coupled to the input terminal, and a second electrode of the first transistor is coupled to the first node.

3. The shift register according to claim 1, wherein the input circuit is further coupled to the first voltage terminal; and the input circuit is configured to transmit the input signal to the first node in response to the first clock signal and the first voltage of the first voltage terminal.

4. The shift register according to claim 3, wherein the input circuit includes:
a first input sub-circuit coupled to the first clock signal terminal, the input terminal and a third node, wherein the first input sub-circuit is configured to transmit the input signal to the third node in response to the first clock signal; and
a second input sub-circuit coupled to the third node, the first voltage terminal and the first node, wherein the second input sub-circuit is configured to connect the first input sub-circuit to the first node in response to the first voltage of the first voltage terminal.

5. The shift register according to claim 4, wherein the first input sub-circuit includes a second transistor; and a control electrode of the second transistor is coupled to the first clock signal terminal, a first electrode of the second transistor is coupled to the input terminal, and a second electrode of the second transistor is coupled to the third node; and
the second input sub-circuit includes a third transistor; and a control electrode of the third transistor is coupled to the first voltage terminal, a first electrode of the third transistor is coupled to the third node, and a second electrode of the third transistor is coupled to the first node.

6. The shift register according to claim 1, wherein the first control circuit includes a fourth transistor; and a control electrode of the fourth transistor is coupled to the first clock signal terminal, a first electrode of the fourth transistor is coupled to the first voltage terminal, and a second electrode of the fourth transistor is coupled to the second node.

7. The shift register according to claim 1, wherein the first output circuit includes:
a fifth transistor, wherein a control electrode of the fifth transistor is coupled to the first node, a first electrode of the fifth transistor is coupled to the second clock signal terminal, and a second electrode of the fifth transistor is coupled to the output terminal; and
a first capacitor, wherein a first terminal of the first capacitor is coupled to the first node, and a second terminal of the first capacitor is coupled to the output terminal.

8. The shift register according to claim 1, wherein the second output circuit includes:
a sixth transistor, wherein a control electrode of the sixth transistor is coupled to the second node, a first electrode of the sixth transistor is coupled to the second voltage terminal, and a second electrode of the sixth transistor is coupled to the output terminal; and
a second capacitor, wherein a first terminal of the second capacitor is coupled to the second voltage terminal, and a second terminal of the second capacitor is coupled to the second node.

9. The shift register according to claim 1, further comprising a second control circuit coupled to the second node, the second voltage terminal, and the output terminal;
wherein the second control circuit is configured to transmit the second voltage of the second voltage terminal to the second node in response to the output signal at the output terminal.

10. The shift register according to claim 9, wherein the second control circuit includes a seventh transistor; and a control electrode of the seventh transistor is coupled to the output terminal, a first electrode of the seventh transistor is coupled to the second voltage terminal, and a second electrode of the seventh transistor is coupled to the second node.

11. The shift register according to claim 4, further comprising a third control circuit coupled to the second clock signal terminal, the second voltage terminal, the second node and the third node, wherein the third control circuit is configured to transmit the second voltage of the second voltage terminal to the third node in response to the voltage of the second node and the second clock signal received at the second clock signal terminal.

12. The shift register according to claim 11, wherein the third control circuit includes:
an eighth transistor, wherein a control electrode of the eighth transistor is coupled to the second node, and a first electrode of the eighth transistor is coupled to the second voltage terminal; and
a ninth transistor, wherein a control electrode of the ninth transistor is coupled to the second clock signal terminal, a first electrode of the ninth transistor is coupled to a second electrode of the eighth transistor, and a second electrode of the ninth transistor is coupled to the third node.

13. The shift register according to claim 1, further comprising a storage circuit coupled to the output terminal and a fixed voltage terminal, wherein the storage circuit is configured to store the output signal at the output terminal.

14. The shift register according to claim 13, wherein the storage circuit includes a third capacitor; and a first terminal of the third capacitor is coupled to the output terminal, and a second terminal of the third capacitor is coupled to the fixed voltage terminal.

15. The shift register according to claim 1, further comprising a second control circuit and a third control circuit; wherein
the input circuit includes a first transistor, a control electrode of the first transistor is coupled to the first clock signal terminal, a first electrode of the first transistor is coupled to the input terminal, and a second electrode of the first transistor is coupled to the first node;
the first control circuit includes a fourth transistor; a control electrode of the fourth transistor is coupled to the first clock signal terminal, a first electrode of the fourth transistor is coupled to the first voltage terminal, and a second electrode of the fourth transistor is coupled to the second node;
the first output circuit includes a fifth transistor and a first capacitor; a control electrode of the fifth transistor is coupled to the first node, a first electrode of the fifth transistor is coupled to the second clock signal terminal, and a second electrode of the fifth transistor is coupled to the output terminal; a first terminal of the first capacitor is coupled to the first node, and a second terminal of the first capacitor is coupled to the output terminal;
the second output circuit includes a sixth transistor and a second capacitor; a control electrode of the sixth transistor is coupled to the second node, a first electrode of the sixth transistor is coupled to the second voltage terminal, and a second electrode of the sixth transistor is coupled to the output terminal; a first terminal of the second capacitor is coupled to the second voltage terminal, and a second terminal of the second capacitor is coupled to the second node;
the second control circuit includes a seventh transistor; a control electrode of the seventh transistor is coupled to the output terminal, a first electrode of the seventh transistor is coupled to the second voltage terminal, and a second electrode of the seventh transistor is coupled to the second node; and
the third control circuit includes an eighth transistor and a ninth transistor; a control electrode of the eighth transistor is coupled to the second node, and a first electrode of the eighth transistor is coupled to the second voltage terminal; and a control electrode of the ninth transistor is coupled to the second clock signal terminal, a first electrode of the ninth transistor is coupled to a second electrode of the eighth transistor, and a second electrode of the ninth transistor is coupled to the first node.

16. The shift register according to claim 1, further comprising a second control circuit and a third control circuit; wherein
the input circuit is further coupled to the first voltage terminal, and the input circuit includes a second transistor and a third transistor; a control electrode of the second transistor is coupled to the first clock signal terminal, a first electrode of the second transistor is coupled to the input terminal, and a second electrode of the second transistor is coupled to a third node; a control electrode of the third transistor is coupled to the first voltage terminal, a first electrode of the third transistor is coupled to the third node, and a second electrode of the third transistor is coupled to the first node;
the first control circuit includes a fourth transistor; a control electrode of the fourth transistor is coupled to the first clock signal terminal, a first electrode of the fourth transistor is coupled to the first voltage terminal, and a second electrode of the fourth transistor is coupled to the second node;
the first output circuit includes a fifth transistor and a first capacitor; a control electrode of the fifth transistor is coupled to the first node, a first electrode of the fifth transistor is coupled to the second clock signal terminal, and a second electrode of the fifth transistor is coupled to the output terminal; a first terminal of the first capacitor is coupled to the first node, and a second terminal of the first capacitor is coupled to the output terminal;
the second output circuit includes a sixth transistor and a second capacitor; a control electrode of the sixth transistor is coupled to the second node, a first electrode of the sixth transistor is coupled to the second voltage terminal, and a second electrode of the sixth transistor is coupled to the output terminal; a first terminal of the second capacitor is coupled to the second voltage terminal, and a second terminal of the second capacitor is coupled to the second node;
the second control circuit includes a seventh transistor, a control electrode of the seventh transistor is coupled to the output terminal, a first electrode of the seventh transistor is coupled to the second voltage terminal, and a second electrode of the seventh transistor is coupled to the second node; and
the third control circuit includes an eighth transistor and a ninth transistor; a control electrode of the eighth transistor is coupled to the second node, and a first electrode of the eighth transistor is coupled to the second voltage terminal; and a control electrode of the ninth transistor is coupled to the second clock signal terminal, a first electrode of the ninth transistor is coupled to a second electrode of the eighth transistor, and a second electrode of the ninth transistor is coupled to the third node.

17. A gate driving circuit, comprising a plurality of shift registers, at least one of the plurality of shift registers being the shift register according to claim 1.

18. A display apparatus, comprising the gate driving circuit according to claim 17.

19. A driving method of a shift register, the shift register being the shift register according to claim 1, the driving method comprising:
transmitting, by the input circuit, the input signal received at the input terminal to the first node in response to the first clock signal received at the first clock signal terminal;
transmitting, by the first control circuit, the first voltage of the first voltage terminal to the second node in response to the first clock signal received at the first clock signal terminal;
transmitting, by the first output circuit, the second clock signal received at the second clock signal terminal to the output terminal in response to the voltage of the first node; and
transmitting, by the second output circuit, the second voltage of the second voltage terminal to the output terminal in response to the voltage of the second node.

20. The driving method according to claim 19, wherein the input circuit includes a first input sub-circuit and a second input sub-circuit; and transmitting, by the input circuit, the input signal received at the input terminal to the first node in response to the first clock signal received at the first clock signal terminal includes:
transmitting, by the first input sub-circuit, the input signal in response to the first clock signal; and
transmitting, by the second input sub-circuit, the input signal to the first node in response to the first voltage of the first voltage terminal.
